(19) United States
(12) Patent Application Publication
(10) Pub. No.: US 2016/0163552 A1
(43) Pub. Date: Jun. 9, 2016

(54) NON-VOLATILE MEMORY AND FABRICATING METHOD THEREOF

(71) Applicant: Powerchip Technology Corporation, Hsinchu (TW)

(72) Inventors: Cheng-Yuan Hsu, Hsinchu City (TW); Chen-Fu Chang, Taichung City (TW); Hui-Huang Chen, Changhua County (TW); Tzung-Hua Ying, Hsinchu City (TW)

(21) Appl. No.: 14/621,403

(22) Filed: Feb. 13, 2015

(30) Foreign Application Priority Data
Dec. 5, 2014 (TW) 103142426

(51) Int. Cl. H01L 21/28; H01L 29/423; H01L 27/115

(52) U.S. Cl. CPC H01L 21/28273; H01L 27/11521; H01L 29/42332

(57) ABSTRACT

A non-volatile memory including a substrate, a first stacked structure, a second stacked structure, a fifth conductive layer, a first doped region, and a second doped region is provided. The first stacked structure includes a first conductive layer and a second conductive layer stacked on the substrate in order and isolated from each other. The second stacked structure is separately disposed from the first stacked structure and includes a third conductive layer and a fourth conductive layer stacked on the substrate in order and connected to each other. The fifth conductive layer is disposed on the substrate at one side of the first stacked structure away from the second stacked structure. The first doped region is disposed in the substrate below the fifth conductive layer. The second doped region is disposed in the substrate at one side of the second stacked structure away from the first stacked structure.

### CROSS-REFERENCE TO RELATED APPLICATION

This application claims the priority benefit of Taiwan application serial no. 103142426, filed on Dec. 5, 2014. The entirety of the above-mentioned patent application is hereby incorporated by reference herein and made a part of this specification.

### BACKGROUND OF THE INVENTION

1. Field of the Invention

The invention relates to a memory and a fabricating method thereof, and more particularly, to a non-volatile memory and a fabricating method thereof.

2. Description of Related Art

Since a non-volatile memory device has the advantage of retaining stored data when the power is cut off, the non-volatile memory device has become a widely adopted memory device in personal computers and electronic equipment.

The typical non-volatile memory device includes a floating gate and a control gate. The control gate is disposed on the floating gate, and dielectric layers are respectively disposed between the floating fate and a substrate, and the floating gate and the control gate.

When an erase operation is performed on the non-volatile memory, the issue of over-erase is present, thus causing misjudgment of data. Therefore, to solve the issue of over-erase of a device, many non-volatile memories adopt the design of a split gate.

A characteristic of a non-volatile memory structure having a split gate is that, in addition to having a control gate and a floating gate, the non-volatile memory structure having a split gate also has a select gate located at one side of the control gate and the floating gate. In this way, when the over-erase phenomenon is too severe, such that the channel below the floating gate is continuously open even when an operating voltage is not applied to the control gate, the channel below the select gate can still remain in a closed state, and therefore misjudgment of data can be prevented.

However, the fabrication process of a non-volatile memory structure having a split gate is too complex and component size (such as linewidth of select gate) is not readily controlled, which are current issues industries urgently need to solve.

### SUMMARY OF THE INVENTION

The invention provides a non-volatile memory and a fabricating method thereof capable of effectively reducing fabricating steps and providing better control of component size.

The invention provides a non-volatile memory including a substrate, a first stacked structure, a second stacked structure, a fifth conductive layer, a first doped region, and a second doped region. The first stacked structure includes a first conductive layer and a second conductive layer. The first conductive layer and the second conductive layer are stacked on the substrate in order and isolated from each other. The second stacked structure is separately disposed from the first stacked structure and includes a third conductive layer and a fourth conductive layer. The third conductive layer and the fourth conductive layer are stacked on the substrate in order and connected to each other. The fifth conductive layer is disposed on the substrate at one side of the first stacked structure away from the second stacked structure. The first doped region is disposed in the substrate below the fifth conductive layer. The second doped region is disposed in the substrate at one side of the second stacked structure away from the first stacked structure.

According to an embodiment of the invention, the non-volatile memory further includes a first dielectric layer disposed between the first conductive layer and the substrate and between the third conductive layer and the substrate.

According to an embodiment of the invention, in the non-volatile memory, the first stacked structure further includes a second dielectric layer disposed between the first conductive layer and the second conductive layer. The second stacked structure further includes a third dielectric layer disposed between the third conductive layer and the fourth conductive layer and having an opening. The fourth conductive layer passes through the opening and is connected to the third conductive layer.

According to an embodiment of the invention, in the non-volatile memory, the first stacked structure further includes a first spacer disposed on a sidewall of the second conductive layer and located on a portion of the first conductive layer. The second stacked structure further includes a second spacer disposed on a sidewall of the fourth conductive layer and located on a portion of the third conductive layer.

According to an embodiment of the invention, in the non-volatile memory, the first conductive layer and the third conductive layer are, for instance, derived from the same conductive material layer.

According to an embodiment of the invention, in the non-volatile memory, the second conductive layer and the fourth conductive layer are, for instance, derived from the same conductive material layer.

According to an embodiment of the invention, in the non-volatile memory, the shape of the second stacked structure is, for instance, a rectangle.

According to an embodiment of the invention, the non-volatile memory further includes a fourth dielectric layer disposed between the first stacked structure and the second stacked structure.

According to an embodiment of the invention, the non-volatile memory further includes a fifth dielectric layer disposed between the fifth conductive layer and the first stacked structure and between the fifth conductive layer and the substrate.

According to an embodiment of the invention, the non-volatile memory further includes a third stacked structure and a fourth stacked structure. The third stacked structure and the first stacked structure are, for instance, the same components, and are symmetrically disposed at two sides of the fifth conductive layer. The fourth stacked structure and the second stacked structure are, for instance, the same components, and are symmetrically disposed at two sides of the fifth conductive layer.

According to an embodiment of the invention, the non-volatile memory further includes a third doped region. The third doped region and the second doped region are symmetrically disposed in the substrate at two sides of the fifth conductive layer.

The invention provides a fabricating method of a non-volatile memory. The fabricating method includes following steps. A first stacked structure and a second stacked structure separately disposed are formed on a substrate. The first stacked structure includes a first conductive layer and a second conductive layer. The first conductive layer and the second conductive layer are stacked on the substrate in order and isolated from each other. The second stacked structure includes a third conductive layer and a fourth conductive layer. The third conductive layer and the fourth conductive layer are stacked on the substrate in order and connected to each other. A fifth conductive layer is formed on the substrate at one side of the first stacked structure away from the second stacked structure. A first doped region is formed in the substrate below the fifth conductive layer. A second doped region is formed in the substrate at one side of the second stacked structure away from the first stacked structure.

According to an embodiment of the invention, the fabricating method of a non-volatile memory further includes forming a first dielectric layer between the first stacked structure and the substrate and between the second stacked structure and the substrate.

According to an embodiment of the invention, in the fabricating method of a non-volatile memory, the first stacked structure further includes a second dielectric layer, and the second stacked structure further includes a third dielectric layer. The second dielectric layer is disposed between the first conductive layer and the second conductive layer. The third dielectric layer is disposed between the third conductive layer and the fourth conductive layer and has an opening, and the fourth conductive layer passes through the opening and is connected to the third conductive layer.

According to an embodiment of the invention, in the fabricating method of a non-volatile memory, the forming method of the first stacked structure and the second stacked structure includes the following steps. A first conductive material layer, a first dielectric material layer, a second conductive material layer, and a patterned mask layer are formed on a substrate in order. An opening is formed in the first dielectric material layer. A portion of the second conductive material layer, a portion of the first dielectric material layer, and a portion of the first conductive material layer are removed by using the patterned mask layer as a mask to respectively the second conductive layer and the fourth conductive layer, the second dielectric layer and the third dielectric layer, and the first conductive layer and the third conductive layer.

According to an embodiment of the invention, the fabricating method of a non-volatile memory further includes the following steps. A first spacer is formed on a sidewall of the second conductive layer, and the first spacer is located on a portion of the first conductive layer. A second spacer is formed on a sidewall of the fourth conductive layer, and the second spacer is located on a portion of the third conductive layer.

According to an embodiment of the invention, the fabricating method of a non-volatile memory further includes forming a fourth dielectric layer between the first stacked structure and the second stacked structure.

According to an embodiment of the invention, the fabricating method of a non-volatile memory further includes forming a fifth dielectric layer between the fifth conductive layer and the first stacked structure and between the fifth conductive layer and the substrate.

According to an embodiment of the invention, the fabricating method of a non-volatile memory further includes forming a third stacked structure and a fourth stacked structure on the substrate. The third stacked structure and the first stacked structure are, for instance, the same components, and are symmetrically disposed at two sides of the fifth conductive layer. The fourth stacked structure and the second stacked structure are, for instance, the same components, and are symmetrically disposed at two sides of the fifth conductive layer.

According to an embodiment of the invention, the fabricating method of a non-volatile memory further includes forming a third doped region in the substrate. The third doped region and the second doped region are symmetrically disposed at two sides of the fifth conductive layer.

Based on the above, in the non-volatile memory and the fabricating method thereof provided in the invention, since the first conductive layer and the second conductive layer can be formed via a self-aligned manner, and the third conductive layer and the fourth conductive layer connected to each other can be formed via a self-aligned manner, fabricating steps can be effectively reduced and component size is better controlled.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are cross-sectional views of the fabricating process of a non-volatile memory of an embodiment of the invention.

### DESCRIPTION OF THE EMBODIMENTS

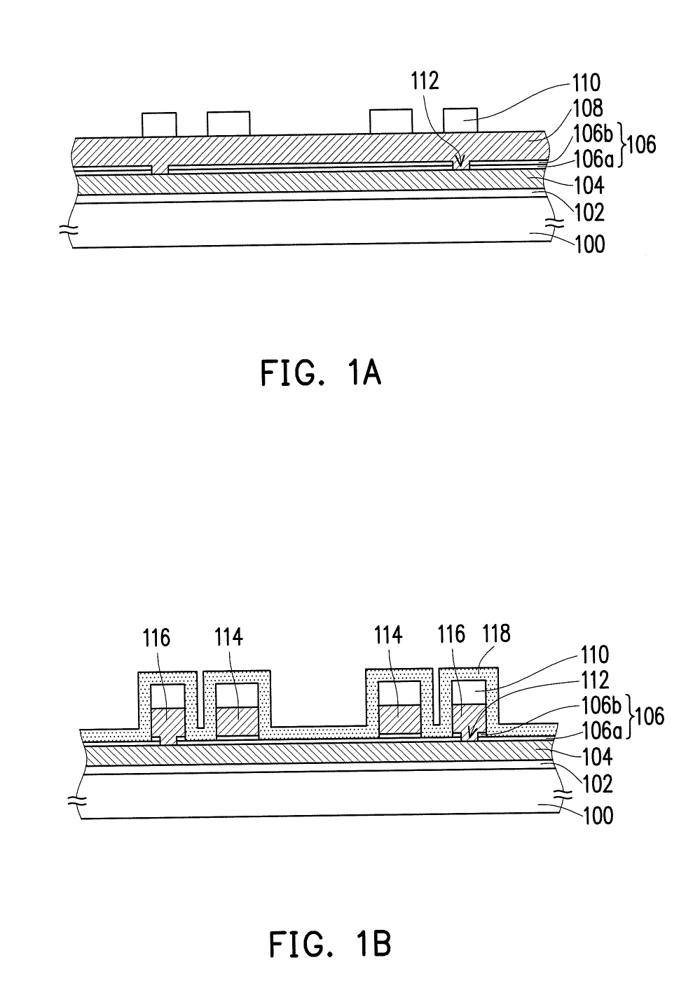

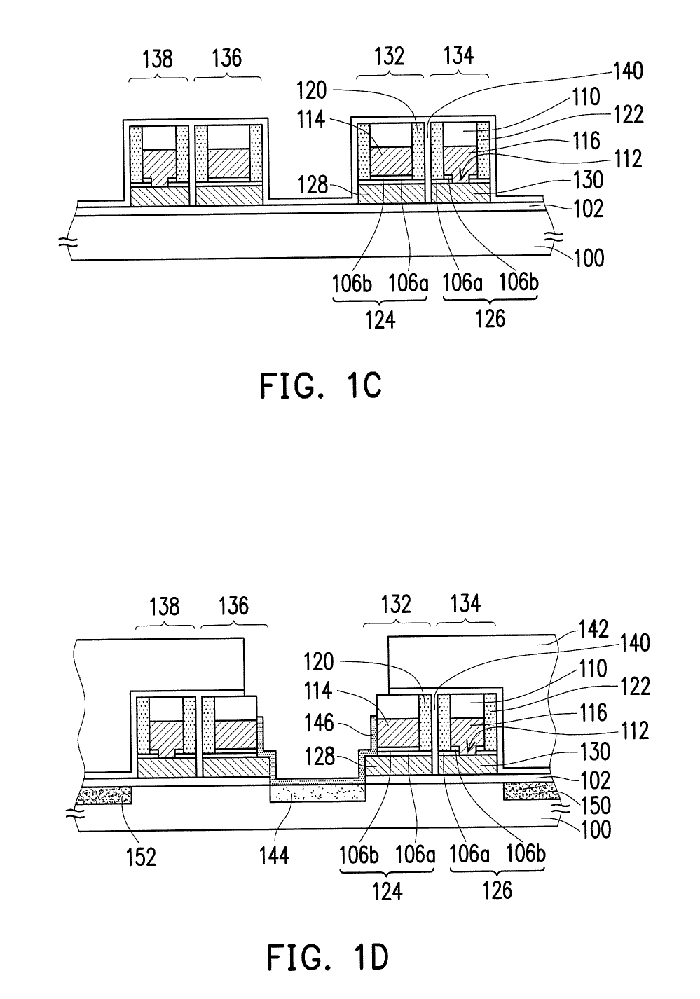

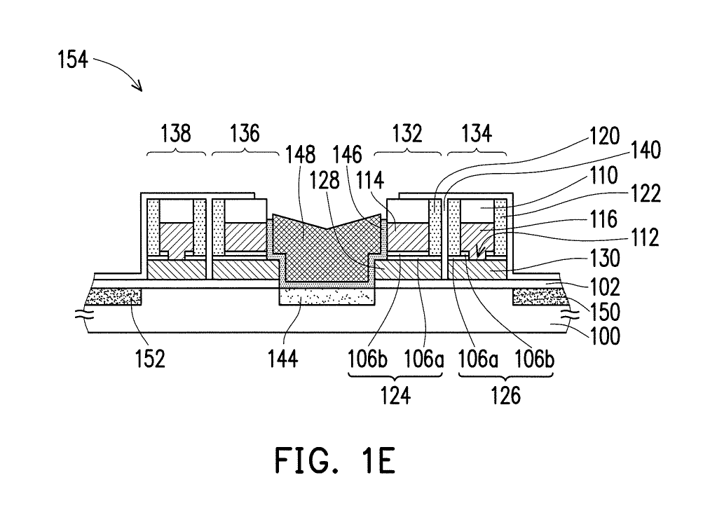

FIG. 1A to FIG. 1E are cross-sectional views of the fabricating process of a non-volatile memory of an embodiment of the invention.

Referring to FIG. 1A, a dielectric layer 102 can be optionally formed on a substrate 100. The substrate 100 is, for instance, a silicon substrate. The material of the dielectric layer 102 is, for instance, silicon oxide. The forming method of the dielectric layer 102 is, for instance, a thermal oxidation method or a chemical vapor deposition method.

A conductive material layer 104, a dielectric material layer 106, a conductive material layer 108, and a patterned mask layer 110 are formed on the dielectric layer 102 in order.

The material of the conductive material layer 104 is, for instance, a conductive material such as doped polysilicon. The forming method of the conductive material layer 104 is, for instance, a chemical vapor deposition method.

The dielectric material layer 106 is, for instance, a composite dielectric layer. The forming method of the dielectric material layer 106 is, for instance, a chemical vapor deposition method. In the present embodiment, the dielectric material layer 106 is exemplified by a composite dielectric layer formed by a silicon oxide layer 106a and a silicon nitride layer 106b, but the invention is not limited thereto. In other embodiments, the dielectric material layer 106 can also be a composite dielectric layer of silicon oxide layer/silicon nitride layer/silicon oxide layer or a composite dielectric layer of silicon oxide layer/silicon nitride layer/silicon oxide layer/silicon nitride layer. Those having ordinary skill in the art can adjust the material of the dielectric material layer 106 according to product design requirements.

Moreover, an opening 112 is formed in the first dielectric material layer 106. The forming method of the opening 112 includes, for instance, performing a patterning process on the dielectric material layer 106.

The material of the conductive material layer 108 is, for instance, a conductive material such as doped polysilicon. The forming method of the conductive material layer 108 is, for instance, a chemical vapor deposition method.

The material of the patterned mask layer 110 is, for instance, silicon nitride. The forming method of the patterned mask layer 110 includes, for instance, forming a mask material layer (not shown) on the conductive material layer 108, and then performing a patterning process on the mask material layer. The forming method of the mask material layer is, for instance, a chemical vapor deposition method.

Referring to FIG. 1B, a portion of the conductive material layer 108 is removed by using the patterned mask layer 110 as a mask to form a conductive layer 114 and a conductive layer 116. The removal method of a portion of the conductive material layer 108 is, for instance, a dry etching method. The width of the conductive layer 116 is, for instance, greater than the width of the opening 112. In the present embodiment, the conductive layer 114 and the conductive layer 116 are, for instance, derived from the same conductive material layer 108.

A portion of the dielectric material layer 106 can optionally be removed by using the patterned mask layer 110 as a mask. In the present embodiment, a portion of the silicon nitride layer 106b is removed to expose a portion of the silicon oxide layer 106a, but the invention is not limited thereto. In other embodiments, a portion of the silicon nitride layer 106b and a portion of the silicon oxide layer 106a can also be removed to expose a portion of the conductive material layer 104. The removal method of a portion of the dielectric material layer 106 is, for instance, a dry etching method.

Then, a conformal spacer material layer 118 can optionally be formed. The spacer material layer 118 covers the patterned mask layer 110, the conductive layer 114, the conductive layer 116, and the dielectric material layer 106. The material of the spacer material layer 118 is, for instance, silicon oxide or silicon nitride. The forming method of the spacer material layer 118 is, for instance, a chemical vapor deposition method or a thermal oxidation method.

Referring to FIG. 1C, an etch-back process is performed on the spacer material layer 118 to respectively form a spacer 120 and a spacer 122 on a sidewall of each of the conductive layer 114 and the conductive layer 116, and the spacer 120 and the spacer 122 are located on a portion of the conductive material layer 104.

A portion of the dielectric material layer 106 is removed by using the patterned mask layer 110, the spacer 120, and the spacer 122 as a mask to form the dielectric layer 124 and the dielectric layer 126. The removal method of a portion of the dielectric material layer 106 is, for instance, a dry etching method.

A portion of the conductive material layer 104 is removed by using the patterned mask layer 110, the spacer 120, and the spacer 122 as a mask to form the conductive layer 128 and the conductive layer 130. The removal method of a portion of the conductive material layer 104 is, for instance, a dry etching method. In the present embodiment, the conductive layer 128 and the conductive layer 130 are, for instance, derived from the same conductive material layer 104.

After performing the above steps, a stacked structure 132 and a stacked structure 134 separately disposed are formed on the substrate 100. The shape of the stacked structure 134 is, for instance, a rectangle.

The stacked structure 132 includes a conductive layer 128 and a conductive layer 114. The conductive layer 128 and the conductive layer 114 can respectively be used as a floating gate and a control gate. The conductive layer 128 and the conductive layer 114 are stacked on the substrate 100 in order and isolated from each other. In the present embodiment, the stacked structure 132 can further include a dielectric layer 124 and a spacer 120. The dielectric layer 124 is disposed between the conductive layer 128 and the conductive layer 114. The spacer 120 is disposed on a sidewall of the conductive layer 114 and located on a portion of the conductive layer 128.

The stacked structure 134 includes a conductive layer 130 and a conductive layer 116. The conductive layer 130 and the conductive layer 116 are stacked on the substrate 100 in order and connected to each other. The conductive layer 130 and the conductive layer 116 connected to each other can be used as select gates. In the present embodiment, the stacked structure 134 can further include a dielectric layer 126 and a spacer 122. The dielectric layer 126 is disposed between the conductive layer 130 and the conductive layer 116 and has an opening 112. The conductive layer 116 passes through the opening 112 and is connected to the conductive layer 130. The spacer 122 is disposed on a sidewall of the conductive layer 116 and located on a portion of the conductive layer 130.

Moreover, in the present embodiment, when forming the stacked structure 132 and the stacked structure 134, a stacked structure 136 and a stacked structure 138 can further be formed on the substrate 100. The stacked structure 136 and the stacked structure 132 are, for instance, the same components, and are symmetrically disposed on the substrate 100. The stacked structure 138 and the stacked structure 134 are, for instance, the same components, and are symmetrically disposed on the substrate 100. The constituent components of the stacked structure 136 and the stacked structure 138 are respectively similar to the constituent components of the stacked structure 132 and the stacked structure 134, and are therefore not repeated herein.

A dielectric layer 140 can be optionally formed between the stacked structure 132 and the stacked structure 134. The dielectric layer 140 can be used to completely fill the gap between the stacked structure 132 and the stacked structure 134 and the gap between the stacked structure 136 and the stacked structure 138 for isolating the stacked structure 132 and the stacked structure 134 and for isolating the stacked structure 136 and the stacked structure 138. The material of the dielectric layer 140 is, for instance, silicon oxide. The forming method of the dielectric layer 140 is, for instance, a thermal oxidation method or a chemical vapor deposition method. Moreover, the dielectric layer 140 can further cover the stacked structure 132, the stacked structure 134, the stacked structure 136, the stacked structure 138, and the dielectric layer 102.

Referring to FIG. 1D, a patterned photoresist layer 142 is formed. The patterned photoresist layer 142 exposes the region between the stacked structure 132 and the stacked structure 136 in which an erase gate is to be formed. Moreover, the patterned photoresist layer 142 can further optionally expose a portion of the stacked structure 132 and a portion of the stacked structure 136.

A doped region 144 is formed in the substrate 100 between the stacked structure 132 and the stacked structure 136 by using the patterned photoresist layer 142 as a mask. The forming method of the doped regions 144 is, for instance, an ion implantation method.

The dielectric layer 140, the spacer 120, and the dielectric layer 102 exposed by the patterned photoresist layer 142 can optionally be removed to expose the substrate 100. The removal method of the dielectric layer 140, the spacer 120, and the dielectric layer 102 exposed by the patterned photoresist layer 142 is, for instance, a wet etching method, such as performing etching by using dilute hydrofluoric acid (DHF).

A dielectric layer 146 is formed on a sidewall of each of the stacked structure 132 and the stacked structure 136 exposed by the patterned photoresist layer 142 and the substrate 100. The material of the dielectric layer 146 is, for instance, silicon oxide. A forming method of the dielectric layer 146 is, for instance, a thermal oxidation method.

Referring to FIG. 1E, the patterned photoresist layer 142 is removed. The removal method of the patterned photoresist layer 142 is, for instance, a dry photoresist removal method or a wet photoresist removal method.

A conductive layer 148 is formed on the substrate 100 at one side of the stacked structure 132 away from the stacked structure 134. The conductive layer 148 can be used as an erase gate. The material of the conductive layer 148 is, for instance, a conductive material such as doped polysilicon. The forming method of the conductive layer 148 includes, for instance, forming a conductive material layer (not shown) via a chemical vapor deposition method, and then removing the conductive material layer outside the region in which the conductive layer 148 is to be formed.

A doped region 150 is formed in the substrate 100 at one side of the stacked structure 134 away from the stacked structure 132. The forming method of the doped regions 150 is, for instance, an ion implantation method. Moreover, when forming the doped region 150, a doped region 152 can further be formed in the substrate 100. The doped region 152 and the doped region 150 are symmetrically disposed at two sides of the conductive layer 148.

In the above embodiments, the basic structure of the non-volatile memory 154 is fabricated, but the invention is not limited thereto. Those having ordinary skill in the art can adjust the structure of the non-volatile memory 154 according to product design requirements. For instance, a spacer can further be optionally formed on a sidewall of each of the stacked structure 134 and the stacked structure 138, or a lightly-doped drain (LDD) can be formed in the substrate 100.

In the following, the structure of the non-volatile memory 154 in the present embodiment is described via FIG. 1E.

Referring to FIG. 1E, the non-volatile memory 154 includes a substrate 100, a stacked structure 132, a stacked structure 134, a conductive layer 148, a doped region 144, and a doped region 150.

The stacked structure 132 includes a conductive layer 128 and a conductive layer 114. The conductive layer 128 and the conductive layer 114 are stacked on the substrate 100 in order and isolated from each other. The stacked structure 132 can further optionally include at least one of a dielectric layer 124 and a spacer 120. The dielectric layer 124 is disposed between the conductive layer 128 and the conductive layer 114. The spacer 120 is disposed on a sidewall of the conductive layer 114 and located on a portion of the conductive layer 128.

The stacked structure 134 is separately disposed from the stacked structure 132 and includes a conductive layer 130 and a conductive layer 116. The conductive layer 130 and the conductive layer 116 are stacked on the substrate 100 in order and connected to each other. The stacked structure 134 can further optionally include at least one of a dielectric layer 126 and a spacer 122. The dielectric layer 126 is disposed between the conductive layer 130 and the conductive layer 116 and has an opening 112. The conductive layer 116 passes through the opening 112 and is connected to the conductive layer 130. The spacer 122 is disposed on a sidewall of the conductive layer 116 and located on a portion of the conductive layer 130.

The conductive layer 148 is disposed on the substrate 100 at one side of the stacked structure 132 away from the stacked structure 134. The doped region 144 is disposed in the substrate 100 below the conductive layer 148. The doped region 150 is disposed in the substrate 100 at one side of the stacked structure 134 away from the stacked structure 132.

Moreover, the non-volatile memory 154 can further optionally include at least one of a patterned mask layer 110, a dielectric layer 102, a dielectric layer 140, and a dielectric layer 146. The patterned mask layer 110 is disposed on the conductive layer 114 and the conductive layer 116. The dielectric layer 102 is disposed between the conductive layer 128 of the stacked structure 132 and the substrate 100 and between the conductive layer 130 of the stacked structure 134 and the substrate 100. The dielectric layer 140 is disposed between the stacked structure 132 and the stacked structure 134. The dielectric layer 146 is disposed between the conductive layer 148 and the stacked structure 132 and between the conductive layer 148 and the substrate 100.

Moreover, the non-volatile memory 154 can further optionally include a stacked structure 136, a stacked structure 138, and a doped region 152. The stacked structure 136 and the stacked structure 132 are, for instance, the same components, and are symmetrically disposed at two sides of the conductive layer 148. The stacked structure 138 and the stacked structure 134 are, for instance, the same components, and are symmetrically disposed at two sides of the conductive layer 148. The doped region 152 and the doped region 150 are symmetrically disposed in the substrate 100 at two sides of the conductive layer 148.

Moreover, the material, the forming method, and the efficacy . . . etc. of each component in the non-volatile memory 154 are described in detail above and are therefore not repeated herein.

In the non-volatile memory 154 and the fabricating method thereof of the above embodiments, since the conductive layer 128 and the conductive layer 114 can be formed in a self-aligned manner, and the conductive layer 130 and the conductive layer 116 connected to each other can be formed in a self-aligned manner, the issue of overlay shift can be prevented, and control of component size (such as size of select gate) is easier. At the same time, fabricating steps can be effectively reduced and therefore process complexity can be lowered, and the number of photomasks needed can be reduced, thus lowering fabrication costs.

Based on the above, the above embodiments at least have the following characteristics. Via the non-volatile memory and the fabricating method thereof, fabricating steps can be effectively reduced and component size is better controlled.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A non-volatile memory, comprising:
a substrate;
a first stacked structure, comprising a first conductive layer and a second conductive layer, wherein the first conductive layer and the second conductive layer are stacked on the substrate in order and isolated from each other;
a second stacked structure separately disposed from the first stacked structure, and comprising a third conductive layer and a fourth conductive layer, wherein the third conductive layer and the fourth conductive layer are stacked on the substrate in order and connected to each other;
a fifth conductive layer disposed on the substrate at one side of the first stacked structure away from the second stacked structure;
a first doped region disposed in the substrate below the fifth conductive layer; and
a second doped region disposed in the substrate at one side of the second stacked structure away from the first stacked structure.

2. The non-volatile memory of claim 1, further comprising a first dielectric layer disposed between the first conductive layer and the substrate and between the third conductive layer and the substrate.

3. The non-volatile memory of claim 1, wherein
the first stacked structure further comprises a second dielectric layer disposed between the first conductive layer and the second conductive layer, and
the second stacked structure further comprises a third dielectric layer disposed between the third conductive layer and the fourth conductive layer and having an opening, wherein the fourth conductive layer passes through the opening and is connected to the third conductive layer.

4. The non-volatile memory of claim 1, wherein
the first stacked structure further comprises a first spacer disposed on a sidewall of the second conductive layer and located on a portion of the first conductive layer, and
the second stacked structure further comprises a second spacer disposed on a sidewall of the fourth conductive layer and located on a portion of the third conductive layer.

5. The non-volatile memory of claim 1, wherein the first conductive layer and the third conductive layer are derived from the same conductive material layer.

6. The non-volatile memory of claim 1, wherein the second conductive layer and the fourth conductive layer are derived from the same conductive material layer.

7. The non-volatile memory of claim 1, wherein a shape of the second stacked structure comprises a rectangle.

8. The non-volatile memory of claim 1, further comprising a fourth dielectric layer disposed between the first stacked structure and the second stacked structure.

9. The non-volatile memory of claim 1, further comprising a fifth dielectric layer disposed between the fifth conductive layer and the first stacked structure and between the fifth conductive layer and the substrate.

10. The non-volatile memory of claim 1, further comprising a third stacked structure and a fourth stacked structure, wherein
the third stacked structure and the first stacked structure are the same components, and are symmetrically disposed at two sides of the fifth conductive layer,
the fourth stacked structure and the second stacked structure are the same components, and are symmetrically disposed at two sides of the fifth conductive layer.

11. The non-volatile memory of claim 1, further comprising a third doped region, wherein the third doped region and the second doped region are symmetrically disposed in the substrate at two sides of the fifth conductive layer.

12. A fabricating method of a non-volatile memory, comprising:
forming a first stacked structure and a second stacked structure separately disposed on a substrate, wherein the first stacked structure comprises a first conductive layer and a second conductive layer, the first conductive layer and the second conductive layer are stacked on the substrate in order and isolated from each other, the second stacked structure comprises a third conductive layer and a fourth conductive layer, and the third conductive layer and the fourth conductive layer are stacked on the substrate in order and connected to each other;
forming a fifth conductive layer on the substrate at one side of the first stacked structure away from the second stacked structure;
forming a first doped region in the substrate below the fifth conductive layer; and
forming a second doped region in the substrate at one side of the second stacked structure away from the first stacked structure.

13. The method of claim 12, further comprising forming a first dielectric layer between the first stacked structure and the substrate and between the second stacked structure and the substrate.

14. The method of claim 12, wherein the first stacked structure further comprises a second dielectric layer, the second stacked structure further comprises a third dielectric layer, the second dielectric layer is disposed between the first conductive layer and the second conductive layer, the third dielectric layer is disposed between the third conductive layer and the fourth conductive layer and has an opening, and the fourth conductive layer passes through the opening and is connected to the third conductive layer.

15. The method of claim 14, wherein a forming method of the first stacked structure and the second stacked structure comprises:
forming a first conductive material layer, a first dielectric material layer, a second conductive material layer, and a patterned mask layer on the substrate in order, wherein the opening is formed in the first dielectric material layer; and
removing a portion of the second conductive material layer, a portion of the first dielectric material layer, and a portion of the first conductive material layer by using the patterned mask layer as a mask to respectively form the second conductive layer and the fourth conductive layer, the second dielectric layer and the third dielectric layer, and the first conductive layer and the third conductive layer.

16. The method of claim 12, further comprising:
forming a first spacer on a sidewall of the second conductive layer, and the first spacer is located on a portion of the first conductive layer; and
forming a second spacer on a sidewall of the fourth conductive layer, and the second spacer is located on a portion of the third conductive layer.

17. The method of claim 12, further comprising forming a fourth dielectric layer between the first stacked structure and the second stacked structure.

18. The method of claim 12, further comprising forming a fifth dielectric layer between the fifth conductive layer and the first stacked structure and between the fifth conductive layer and the substrate.

19. The method of claim 12, further comprising forming a third stacked structure and a fourth stacked structure on the substrate, wherein
the third stacked structure and the first stacked structure are the same components, and are symmetrically disposed at two sides of the fifth conductive layer,
the fourth stacked structure and the second stacked structure are the same components, and are symmetrically disposed at two sides of the fifth conductive layer.

20. The method of claim 12, further comprising forming a third doped region in the substrate, wherein the third doped region and the second doped region are symmetrically disposed at two sides of the fifth conductive layer.
